(19) United States
(12) Patent Application Publication
(10) Pub. No.: US 2006/0102466 A1
(43) Pub. Date: May 18, 2006

(54) Ion beam assisted sputtering deposition apparatus

(76) Inventor: Heung-bom Kim, Suwon-si (KR)

Correspondence Address: STANZIONE & KIM, LLP, 919 18TH STREET, N.W., SUITE 440, WASHINGTON, DC, 20006, US

(21) Appl. No.: 11/237,729

(22) Filed: Sep. 29, 2005

(30) Foreign Application Priority Data
Nov. 18, 2004 (KR) 2004-94671

(51) Int. Cl. C23C 14/32; C23C 14/00

(52) U.S. Cl. 204/192.1; 204/298.02

(57) ABSTRACT

A deposition apparatus to deposit deposition particles on an object includes a first vacuum chamber to accommodate the object, a target provided in the first vacuum chamber to discharge the deposition particles to the object, a sputter source to support the target and to cause the target to discharge the deposition particles, a second vacuum chamber to communicate with the first vacuum chamber, and an ion beam source coupled to the second vacuum chamber to discharge an ion beam to the object. Thus, the deposition apparatus reduces consumption of the target and improves adhesion of the object and the deposition layer.

### CROSS-REFERENCE TO RELATED APPLICATIONS

This application claims the benefit under 35 U.S.C. § 119 of Korean Patent Application No. 2004-94671, filed on Nov. 18, 2004, in the Korean Intellectual Property Office, the disclosure of which is incorporated herein in its entirety by reference.

### BACKGROUND OF THE INVENTION

1. Field of the Invention

The present general inventive concept relates to a deposition apparatus, and more particularly, to an ion beam assisted sputtering deposition apparatus to combine strengths of an ion beam assisted deposition apparatus and a sputtering deposition apparatus.

2. Description of the Related Art

Generally, a deposition apparatus forms a deposition layer on an object such as a semiconductor substrate. Deposition methods are classified into physical vapor deposition and chemical vapor deposition. In the physical vapor deposition, particles having high energy collide against a deposition material to discharge deposition particles from the deposition material. The physical vapor deposition is classified into a sputtering method and a vacuum deposition method. In the vacuum deposition method, an ion beam assisted deposition method is used in which an ion beam source generates the ion beam to transmit energy to the discharged deposition particles.

A conventional ion beam assisted deposition apparatus is disclosed in Japanese First Publication No. 1996-119642, and reproduced in FIG. 1. As shown in FIG. 1, a conventional ion beam assisted deposition apparatus 100 comprises a vacuum chamber 110, an object support 111 supporting an object 105, a deposition material 115 provided below the object 105 and discharging the deposition particles by an electron beam generated from an electron beam source 117, and an ion beam source 127 discharging the ion beam to transmit energy to the deposition particles discharged from the deposition material 115.

The vacuum chamber 110 is kept at a vacuum state having a vacuum level of about 0.0001 torr by a vacuum pump 113. The ion beam source 127 usually generates the ion beam having the high energy by being supplied with argon gas.

Thus, the conventional ion beam assisted deposition apparatus 100 deposits the deposition particles, discharged from the deposition material 115 by the electron beam, on the object 105. The ion beam source 127 discharges the ion beam having the high energy to transmit the high energy to the deposition particles, thereby forming a mixing layer between the object 105 and the deposition layer, and improving adhesion of the deposition layer deposited on the object 105.

However, the conventional ion beam assisted deposition apparatus 100 discharges the deposition particles from the deposition material 115 by the electron beam generated from the electron beam source 117, thereby consuming a lot of the deposition material and increasing costs in the case in which high-priced metals are used as the deposition material.

An example of a conventional sputtering deposition apparatus is disclosed in Korean Patent Application No. 2001-77728, and reproduced in FIG. 2. As shown in FIG. 2, a conventional sputtering deposition apparatus 200 comprises a sputter chamber 210, an object support 211 supporting an object 205, a target 215 which is a deposition material discharging deposition particles, and a sputter source 217 supporting the target 215, forming plasma around the target 215, and discharging the deposition particles from the target 215.

The sputter chamber 210 is kept at a vacuum state having a vacuum level between 0.001 and 0.01 torr, and is usually filled with argon gas to generate the plasma.

The sputter source 217 is provided with a magnet or the like to form the plasma around the target 215, and applies a negative voltage to the target 215.

In the conventional sputtering deposition apparatus 200 of FIG. 2, when the target 215 is applied with the negative voltage, the plasma is formed around the target 215. Then, a positive charged ion within the plasma collides against a surface of the target 215, and the deposition particles having energy of dozens or hundreds of eV (electron volt) are sputtered, and deposited on the object 205.

As described above, in the conventional sputtering deposition apparatus 200, the sputtered deposition particles have energy of dozens or hundreds of eV. Thus, it is difficult to form the mixing layer between the object and the deposition layer, and to improve the adhesion between the object and the deposition layer.

Accordingly, it is desirable to provide a deposition apparatus having strengths of the conventional negative ion assisted deposition apparatus and the sputtering deposition apparatus. Also, it is required to overcome technical difficulties to combine the two deposition apparatuses as the chambers provided in the conventional negative ion assisted deposition apparatus and the sputtering deposition apparatus have different vacuum levels. Thus, it is desirable to develop a deposition apparatus which reduces consumption of a deposition material and improves adhesion of an object and a deposition layer by forming a mixing layer.

### SUMMARY OF THE INVENTION

Accordingly, the present general inventive concept provides an ion beam assisted sputtering deposition apparatus to reduce consumption of a target and to improve adhesion of an object and a deposition layer.

Additional aspects of the present general inventive concept will be set forth in part in the description which follows and, in part, will be obvious from the description, or may be learned by practice of the present general inventive concept.

The foregoing and/or other aspects of the present general inventive concept are achieved by providing a deposition apparatus to deposit deposition particles on an object, comprising a first vacuum chamber to accommodate the object, a target provided in the first vacuum chamber to discharge the deposition particles to the object, a sputter source to support the target and to cause the target to discharge the deposition particles, a second vacuum chamber to communicate with the first vacuum chamber, and an ion beam source coupled to the second vacuum chamber to discharge an ion beam to the object.

The first vacuum chamber and the second vacuum chamber may be respectively provided with a first vacuum pump and a second vacuum pump to control respective vacuum levels thereof.

The deposition apparatus may further comprise an object support coupled to the first vacuum chamber to support the object.

A chamber connecting part may be provided between the first vacuum chamber and the second vacuum chamber to pass the ion beam discharged from the ion beam source therethorugh.

The object may comprise a core of a glass lens.

The first vacuum chamber may maintain a vacuum level substantially from 0.001 to 0.01 torr, and the second vacuum chamber may maintain a vacuum level substantially from 0.00001 to 0.0001 torr.

The ion beam discharged from the ion beam source may have energy of substantially 1 through 10 keV.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic view of a conventional ion beam assisted deposition apparatus;

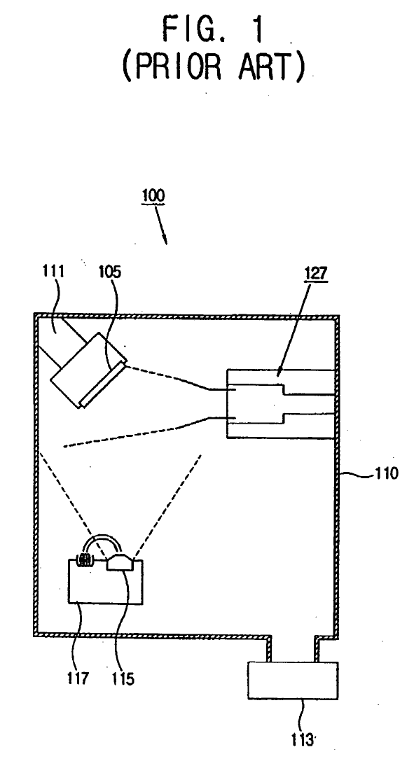

FIG. 2 is a schematic view of a conventional sputtering deposition apparatus; and

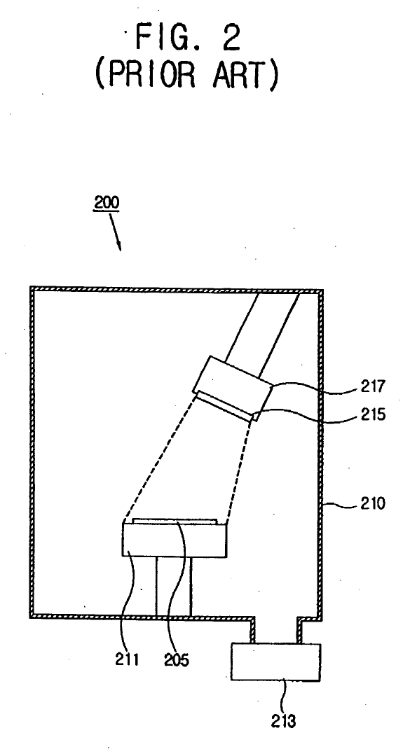

FIG. 3 is a schematic view illustrating a deposition apparatus according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept while referring to the figures.

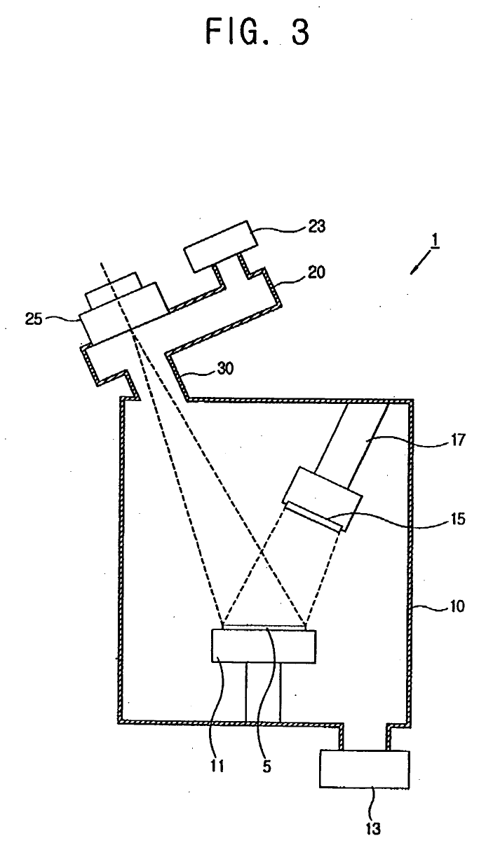

FIG. 3 illustrates a deposition apparatus 1 according to an embodiment of the present general inventive concept. Referring to FIG. 3, a deposition apparatus 1 according to the present embodiment comprises a first vacuum chamber 10 to accommodate an object 5, a target 15 provided in the first vacuum chamber 10 to discharge deposition particles to the object 5, a sputter source 17 to support the target 15 and to discharge the deposition particles from the target 15, a second vacuum chamber 20 to communicate with the first vacuum chamber 10, and an ion beam source 25 provided in the second vacuum chamber 20 to discharge an ion beam to the object 5. The deposition apparatus 1 according to the present embodiment further comprises a chamber connecting part 30 provided between the first vacuum chamber 10 and the second vacuum chamber 20 through which the ion beam discharged from the ion beam source 25 passes.

The object 5 may be provided as a core of a glass lens mold to form a deposition layer by the deposition particles discharged from the target 15. The object 5 is not limited to the core of the glass lens mold. Alternatively, the object 5 may be provided as a substance such as a semiconductor substrate. The object 5 is supported within the first vacuum chamber 10 by an object support 11 coupled to an inner portion of the first vacuum chamber 10.

The object support 11 may be provided at a lower part of the first vacuum chamber 10 to support the object 5. Alternatively, the object support 11 may be provided on upper or a side part of the first vacuum chamber 10 to support the object 5.

The target 15 is a substance to be deposited on the object 5 and is supported by the sputter source 17. The target 15 may be provided as metals such as gold (Au), silver (Ag), platinum (Pt), or Rhenium (Re), but is not limited thereto. The target 15 discharges the deposition particles by plasma generated with the aid of the sputter source 17.

The sputter source 17 is coupled to an inner portion of the first vacuum chamber 10 and supports the target 15. The sputter source 17 applies a negative voltage to the target 15 and includes a magnet or the like to cause gas in the first vacuum chamber 10 to form the plasma around the target 15. Accordingly, the sputter source 17 causes the gas in the first vacuum chamber 10 to form the plasma around the target 15, and the plasma causes the target 15 to discharge the deposition particles. The discharged deposition particles are deposited on the object 5.

A first vacuum pump 13 is provided at the first vacuum chamber 10 to provide a vacuum state having a predetermined vacuum level within the first vacuum chamber 10. The predetermined vacuum level of the first vacuum chamber 10 can vary from 0.001 to 0.01 torr, but is not limited thereto. Alternatively, the vacuum level of the first vacuum chamber 10 may be below 0.001 torr or above 0.01 torr according to various types of the object 5 and the target.15. The first vacuum chamber 10 can be filled with argon gas to form plasma around the target 15 by the sputter source 17. A positive charged ion in the plasma formed around the target 15 collides against a surface of the target 15 and sputters the deposition particles having energy of dozens or hundreds of eV (electron volt). Alternatively, the first vacuum chamber 10 may be filled with gas other than argon to form the plasma around the target 15 by the sputter source 17.

The ion beam source 25 is coupled to the second vacuum chamber 20 and discharges the ion beam toward the object 5. The ion beam discharged by the ion beam source 25 has a predetermined energy to be transmitted to the deposition particles discharged from the target 15. The predetermined energy of the ion beam discharged from the ion beam source 25 can vary from 1 keV to 10 keV, but is not limited thereto. Alternatively, the ion beam energy may be below 1 kev or above 10 keV according to various types of the ion beam source 25, the target 15, etc. The ion beam source 25 may discharge the ion beam using various methods, such as discharging the ion beam by being supplied with argon gas or the like.

A second vacuum pump 23 is provided at the second vacuum chamber 20 to provide a vacuum state having a predetermined vacuum level within the second vacuum 20 to allow the ion beam source 25 to discharge the ion beam. The predetermined vacuum level of the second vacuum chamber 20 can vary from 0.00001 to 0.0001 torr, but is not limited thereto. Alternatively, the vacuum level of the second vacuum chamber 20 may be below 0.00001 torr or above 0.0001 torr according to a type of the ion beam source 25.

The chamber connecting part 30 is provided between the first vacuum chamber 10 and the second vacuum chamber 20 to direct the ion beam discharged from the ion beam source 25 in the second vacuum chamber 20 toward the object 5 in the first vacuum chamber 10. The chamber connecting part 30 communicates between the first vacuum chamber 10 and the second vacuum chamber 20. However, the first vacuum pump 13 and the second vacuum pump 23 are respectively provided in the first vacuum chamber 10 and the second vacuum chamber 20 and operate individually, thereby maintaining the respective vacuum levels in the first and second vacuum chambers 10 and 20.

Operations of the deposition apparatus 1 according to the present embodiment are described below.

When the sputter source 17 applies the negative voltage to the target 15, the argon gas in the first vacuum chamber 10 forms the plasma around the target 15. The positive charged ion in the plasma collides against the surface of the target 15, thereby sputtering the deposition particles having the energy of dozens or hundreds of eV. The deposition particles form a deposition layer to be deposited on the object 5. The ion beam source 25 discharges the ion beam having the energy of 1 keV to 10 keV toward the object 5. The ion beam transmits the energy thereof to the deposition particles, thereby forming the mixing layer between the object 5 and the deposition layer, and improving adhesion between the deposition layer and the object 5.

As described above, a deposition apparatus according to the present general inventive concept reduces consumption of a target by discharging deposition particles from the target in a sputtering method. Also, a deposition apparatus according to the present general inventive concept forms the mixing layer between an object and a deposition layer by using an ion beam source to transmit energy to the deposition particles, and therefore improves adhesion of the deposition layer to the object in an ion beam assisted deposition method.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A deposition apparatus to deposit deposition particles on an object, comprising:
a first vacuum chamber to accommodate the object;
a target provided in the first vacuum chamber to discharge the deposition particles to the object;
a sputter source to support the target and to cause the target to discharge the deposition particles;
a second vacuum chamber provided to communicate with the first vacuum chamber; and
an ion beam source coupled to the second vacuum chamber to discharge an ion beam to the object.

2. The deposition apparatus according to claim 1, wherein the first vacuum chamber and the second vacuum chamber are respectively provided with a first vacuum pump and a second vacuum pump to control respective vacuum levels thereof.

3. The deposition apparatus according to claim 1, further comprising:
an object support coupled to the first vacuum chamber to support the object.

4. The deposition apparatus according to claim 1, further comprising:
a chamber connecting part provided between the first vacuum chamber and the second vacuum chamber to pass the ion beam discharged from the ion beam source therethorugh.

5. The deposition apparatus according to claim 1, wherein the object comprises a core of a glass lens mold.

6. The deposition apparatus according to claim 1, wherein the first vacuum chamber maintains a vacuum level substantially from 0.001 to 0.01 torr, and the second vacuum chamber maintains a vacuum level substantially from 0.00001 to 0.0001 torr.

7. The deposition apparatus according to claim 1, wherein the ion beam discharged from the ion beam source has energy of substantially 1 through 10 keV.

8. The deposition apparatus according to claim 1, wherein the object comprises a semiconductor substrate.

9. The deposition apparatus according to claim 1, wherein the target comprises one of gold, silver, platinum, or Rhenium.

10. A deposition apparatus comprising:
a sputtering vacuum chamber to accommodate an object and a deposition material therein and having a sputtering unit to form a plasma around the deposition materials to cause particles of the deposition material to be deposited on the object;
an ion beam vacuum chamber having an ion beam source to discharge a high energy ion beam; and
a connection portion to communicate between the sputtering vacuum chamber and the ion beam vacuum chamber to direct the discharged high energy ion beam toward the object to increase adherence of the particles of the deposition material to the object.

11. The deposition apparatus according to claim 10, wherein the sputtering vacuum chamber maintains a first vacuum level and the ion beam vacuum chamber maintains a second vacuum level.

12. The deposition apparatus according to claim 10, wherein the sputtering vacuum chamber is filled with argon gas and the sputtering unit applies a negative voltage to the deposition material to cause the argon gas to form the plasma around the deposition material.

13. The deposition apparatus according to claim 10, wherein when the high energy ion beam is direct toward the object, the high energy ion beam forms a mixing layer between the object and the deposition particles to assist the deposition particles to adhere to the object.

14. A deposition apparatus comprising:
a first vacuum chamber to accommodate an object and a target therein;
a sputter source provided in the first vacuum chamber to form a plasma around the target to generate deposition particles from the target to be deposited on the object;
a second vacuum chamber to communicate with the first vacuum chamber; and
an ion beam source therein to discharge an ion beam toward the object to form a mixing layer between the object and the deposition particles to increase adherence of the deposition particles to the object.

15. The deposition apparatus according to claim 14, wherein the first vacuum chamber maintains a first vacuum level and the second vacuum chamber maintains a second vacuum level, and the first vacuum level is greater than the second vacuum level.

16. A deposition apparatus comprising:
a first vacuum chamber maintaining a first vacuum level and including:
an object to receive deposition particles;
a deposition material; and
a sputter source to support the deposition material and to provide a negative charge to the deposition material to generate the deposition particles to be deposited on the object; and
a second vacuum chamber communicating with the first vacuum chamber and maintaining a second vacuum level different from the first vacuum level, the second vacuum chamber including:
an ion beam source to discharge an ion beam into the first vacuum chamber toward the object to transmit energy to the deposition particles adhering to the object.

17. The deposition apparatus according to claim 16, wherein the first vacuum level is greater than the second vacuum level.

18. The deposition apparatus according to claim 16, wherein the first vacuum level is at least ten times greater than the second vacuum level.

19. The deposition apparatus according to claim 16, wherein the first vacuum level is approximately 100 times greater than the second vacuum level.

20. A method of depositing deposition particles on an object, comprising:
sputtering deposition particles toward on object by forming plasma around a deposition material at a first vacuum level; and
discharging an ion beam toward the object to transmit energy to the sputtered deposition particles to increase an adherence level of the deposition particles to the object.

21. The method according to claim 20, wherein the ion beam is discharged at a vacuum level different than the first vacuum level.
